(19) United States
(12) Patent Application Publication
(10) Pub. No.: US 2014/0025326 A1
(43) Pub. Date: Jan. 23, 2014

(54) ELECTRONIC DEVICE INCLUDING CALIBRATION INFORMATION AND METHOD OF USING THE SAME

(71) Applicants: Myungchan Kang, Woodbury, MN (US); Michael C. Palazzotto, Woodbury, MN (US); Stefan H. Gryska, Woodbury, MN (US)

(72) Inventors: Myungchan Kang, Woodbury, MN (US); Michael C. Palazzotto, Woodbury, MN (US); Stefan H. Gryska, Woodbury, MN (US)

(73) Assignee: 3M INNOVATIVE PROPERTIES COMPANY, St. Paul, MN (US)

(21) Appl. No.: 14/007,144

(22) PCT Filed: Mar. 28, 2012
(86) PCT No.: PCT/US12/30928

§ 371 Date: Sep. 24, 2013

Related U.S. Application Data
(60) Provisional application No. 61/475,014, filed on Apr. 13, 2011.

(51) Int. Cl. G01R 27/02

(52) U.S. Cl. CPC G01R 27/02
USPC 702/65

(57) ABSTRACT

Methods of generating a reference correlation for use with an absorptive capacitance vapor sensor and calibration of the absorptive capacitance vapor sensor. An electronic article including the reference correlation and methods of using the same are also disclosed.

### BACKGROUND

The presence of vapors, and their concentration in air, is monitored in many fields of endeavor. Various methods for detecting vapors (e.g., volatile organic compounds (VOCs)) have been developed including, for example, photoionization, gas chromatography, gravimetric techniques, spectroscopic techniques (e.g., mass spectrometry, fluorescence spectroscopy), and absorptive sensing techniques.

In one type of absorptive capacitance sensor, two conductive electrodes, typically parallel (at least one of which is porous) or interdigitated, are separated by a layer of dielectric microporous material into which a vapor to be analyzed (i.e., an analyte vapor) can diffuse. As the amount of vapor absorbed into the dielectric microporous material increases, a change (typically a non-linear change) in the dielectric property of the dielectric microporous material occurs. As used herein the term “absorb” refers to material becoming disposed within the dielectric microporous material, regardless of whether it is merely adsorbed to the pore walls, or dissolved into the bulk dielectric microporous material.

An absorptive capacitance sensor's response is generally dependent on sensor parameters such as, for example, porosity and thickness of the layer of dielectric microporous material and/or electrode area, which may vary somewhat within manufacturing tolerances. Accurately correlating the measured capacitance of the sensor with actual analyte vapor concentration remains a problem that requires costly complex manufacturing processes and/or time-consuming, labor-intensive calibration of individual sensors to overcome.

Measuring capacitance sensor sensitivity at a single analyte vapor concentration generally is accomplished by placing the sensors into a controlled atmosphere chamber, introducing a desired level of a desired analyte vapor, and then measuring the capacitance of the sensor. This process is repeated many times at different concentrations in order to generate a calibration curve for that specific capacitance sensor. Once the calibration curve is generated, capacitance measurements using the sensor at unknown analyte vapor levels can be readily correlated to a unique concentration according to the calibration curve. The procedure is repeated for every solvent for which that capacitance sensor is intended to be used.

Accordingly, in order to ensure that such a sensor will function as intended, it can be necessary to either generate calibration curves for analyte vapors for hundreds or thousands of sensor samples during a manufacturing run, or to reject large numbers of sensors due to falling outside very narrow manufacturing tolerances, in order to ensure proper calibration of the sensors prior to sale.

### SUMMARY

It is presently discovered that, for absorptive capacitance sensors of the type discussed above, the ratio of the first true capacitance (C1) obtained at a fixed concentration of a first vapor to a second true capacitance (C2) obtained using a fixed concentration of a second vapor (i.e., C1/C2) is substantially constant for capacitance sensors of similar design; for example, as produced according to a manufacturing process. In view of this unexpected discovery, the present inventor has developed a method for calibrating such capacitance sensors, and using them in the field that greatly reduces effort and expense as compared to traditional methods. The method can generate calibration libraries that can be included with electronic devices that include or are adapted to be used in conjunction with such absorptive capacitance sensor elements.

Accordingly, in one implementation, the present disclosure provides a method of generating a reference library, the method comprising steps:

a) measuring the capacitance (C_{ref}) of a reference capacitance sensor element while exposed to a known concentration (Y) of a first analyte vapor at standard temperature, wherein the reference capacitance sensor element comprises a layer of dielectric microporous material disposed between and contacting first and second conductive electrodes, and wherein at least a portion of the analyte vapor is absorbed within pores of the dielectric microporous material;

b) measuring the baseline capacitance (C_{ref base}) of the reference capacitance sensor element in the absence of the first analyte vapor at the standard temperature;

c) determining the true reference capacitance C_{ref true}, wherein C_{ref true}=C_{ref}−C_{ref base};

d) measuring the capacitance (Cₙ₂) of the reference capacitance sensor element while exposed to a known concentration of a second analyte vapor;

e) determining a relative reference capacitance (C_{n2 ref}), wherein C_{n2 ref}=(Cₙ₂−C_{ref base})/C_{ref true};

f) repeating steps d) and e) at at least two additional different concentrations of the second analyte vapor;

g) determining a first reference correlation between C_{n2 ref} and the concentration of the second analyte vapor; and

h) recording the first reference correlation onto the computer-readable medium.

In some embodiments, the method further comprises:

i) measuring the capacitance (Cₙ₃) of the reference capacitance sensing element while exposed to a known concentration of a third analyte vapor;

j) determining C_{n3 ref}, wherein C_{n3 ref}=(Cₙ₃−C_{ref base})/C_{ref true};

k) repeating steps i) and j) at at least two additional different concentrations of the third analyte vapor;

l) determining a second reference correlation between C_{n3 ref} and the concentration of the third analyte vapor; and

m) recording the second reference correlation onto the computer-readable medium.

The reference library is useful, for example, in manufacture use of electronic vapor sensors. Accordingly, in another aspect, the present disclosure provides an electronic device comprising a computer-readable medium having information stored thereon, the information comprising a reference library preparable according to a method of the present disclosure.

In some embodiments, the electronic device further comprises:

an operating circuit adapted to power at least an integral capacitance sensor element, wherein the integral capacitance sensor element is of substantially the same construction as the reference capacitance sensor element;

a detection module in electrical communication with the operating circuit, wherein the detection module is adapted to receive an electrical signal from the integral capacitance sensor element;

a processor module communicatively coupled to the detection module and the computer-readable medium, wherein the processor module is adapted to:
obtain the capacitance (Cᵤₙₖ) of the integral capacitance sensor element while exposed to an unknown concentration of a specified analyte vapor for which a corresponding reference correlation exists in the calibration library;
obtain the baseline capacitance (C_{int base}) for the integral capacitance sensor element;
obtain a relative capacitance C_{unk rel}=(Cᵤₙₖ−C_{int base})/R_{conv}, wherein R_{conv} is obtainable by a method comprising:
   exposing the integral sensor element to a known first vapor concentration of the second analyte, wherein the integral sensor element comprises a layer of microporous material disposed between and contacting two electrodes, and wherein at least a portion of the second analyte is adsorbed within pores of the microporous material;
   measuring a first capacitance (C_{int meas1}) of the integral sensor element while the integral sensor element is exposed to a known first vapor concentration of the second analyte;
   measuring a second capacitance (C_{int meas2}) of the integral sensor element while the integral sensor element is exposed to a known second vapor concentration of the second analyte;
   obtaining a difference (ΔC_{int meas}), wherein

ΔC_{int meas}=|C_{int meas1}−C_{int meas2}|;
obtaining a difference (ΔC_{n2 ref}) between a first relative reference capacitance (C_{n2 ref1}) of a reference sensor element at the first vapor concentration of the second analyte and a second relative reference capacitance (C_{n2 ref2}) of the reference sensor element at the second vapor concentration of the analyte, wherein ΔC_{n2 ref}=|C_{n2 ref1}−C_{n2 ref2}|; and
calculating R_{conv} as ΔC_{int meas}/ΔC_{n2 ref};
compare C_{unk rel} to a corresponding reference correlation in the reference library and obtaining the true concentration of the analyte vapor; and
at least one of:
   record the true concentration to the computer readable medium; or
   communicate the true concentration to a display member; and

a communication interface module communicatively coupled to the display member and the processor module,

wherein the operating circuit supplies electrical power to at least the detection module, processor module, display member, and communication interface module.

In some embodiments, the operating circuit is in electrical communication with a heating element adapted to heat the integral capacitance sensor element.

In some embodiments, the electronic device further comprises an integral capacitance sensor element in electrical communication with the operating circuit, wherein the integral capacitance sensor element is of the same construction as reference capacitance sensor element.

In another aspect, the present disclosure provides a method of making a calibrated electronic sensor, the method comprising:

providing an electronic device including an integral capacitance sensor element in electrical communication with the operating circuit according to the present disclosure;

obtaining the baseline capacitance (C_{int base}) for the integral capacitance sensor element;

obtaining R_{conv} by a method comprising:
exposing the integral sensor element to a known first vapor concentration of the second analyte, wherein the integral sensor element comprises a layer of microporous material disposed between and contacting two electrodes, and wherein at least a portion of the second analyte is adsorbed within pores of the microporous material;
measuring a first capacitance (C_{int meas1}) of the integral sensor element while the integral sensor element is exposed to a known first vapor concentration of the second analyte;
measuring a second capacitance (C_{int meas2}) of the integral sensor element while the integral sensor element is exposed to a known second vapor concentration of the second analyte;
obtaining a difference (ΔC_{int meas}), wherein

ΔC_{int meas}=|C_{int meas1}−C_{int meas2}|;
obtaining a difference (ΔC_{n2 ref}) between a first relative reference capacitance (C_{n2 ref1}) of a reference sensor element at the first vapor concentration of the second analyte and a second relative reference capacitance (C_{n2 ref2}) of the reference sensor element at the second vapor concentration of the analyte, wherein ΔCₙ₂ ref=|C_{n2 ref}−C_{n2 ref2}|;
calculating R_{conv} as ΔC_{int meas}/ΔC_{n2 ref}; and

storing R_{conv} and C_{int base} on the electronic device to provide the calibrated electronic sensor.

In another aspect, the present disclosure provides a calibrated electronic sensor made according to the present disclosure.

In another aspect, the present disclosure provides a method of using a calibrated electronic sensor, the method comprising:

providing a calibrated electronic sensor according to the present disclosure;

measuring a capacitance (Cᵤₙₖ) of the integral capacitance sensor element while exposed to the unknown concentration of the specified analyte vapor at the standard temperature;

obtaining a relative capacitance C_{unk rel}=(Cᵤₙₖ−C_{int base})/R_{conv};

comparing C_{unk rel} to a corresponding reference correlation in the reference library and obtaining the true concentration of the analyte vapor; and

at least one of:
recording the true concentration of analyte vapor to the computer readable medium; or

communicating the true concentration of the analyte vapor to the display member.

It is presently discovered that, under some circumstances (e.g., wherein the capacitance sensor elements have high reproducibility, one from another), the ratio of the true capacitance to the baseline capacitance for the sensor elements is essentially constant.

Accordingly, in a second implementation, the present disclosure provides a method of generating a reference library, the method comprising steps:

a) measuring the capacitance (Cₙ₁) of a reference capacitance sensor element while exposed to a known concentration (Y) of a first analyte vapor at standard temperature, wherein the reference capacitance sensor element comprises a layer of dielectric microporous material disposed between and contacting first and second conductive electrodes, and wherein at least a portion of the analyte vapor is absorbed within pores of the dielectric microporous material;

b) measuring the baseline capacitance (C_{ref base}) of the reference capacitance sensor element in the absence of the first analyte vapor at the standard temperature;

c) determining a relative reference capacitance (C_{n1 ref}), wherein

C_{n1 ref}=(Cₙ₁−C_{ref base})/C_{ref base};

d) repeating steps a) and c) at at least two additional different concentrations of the first analyte vapor;

e) determining a first reference correlation between C_{n1 ref} and the concentration of the first analyte vapor; and

f) recording the first reference correlation onto the computer-readable medium.

In some embodiments, the above method further comprises:

g) measuring the capacitance (Cₙ₂) of the reference capacitance sensing element while exposed to a known concentration of a second analyte vapor;

h) determining C_{n2 ref}, wherein C_{n2 ref}=(Cₙ₂−C_{ref base})/C_{ref base};

i) repeating steps g) and h) at at least two additional different concentrations of the second analyte vapor;

j) determining a second reference correlation, wherein the second reference correlation comprises a mathematical or graphical correlation between C_{n2 ref} and the concentration of the second analyte vapor; and

k) recording the second reference correlation onto the computer-readable medium.

In yet another aspect, the present disclosure provides an electronic device comprising a computer-readable medium having information stored thereon, the information comprising a reference library prepared according to the present disclosure.

In some embodiments, the electronic device further comprises:

an operating circuit adapted to power at least an integral capacitance sensor element,

wherein the integral capacitance sensor element is of substantially the same construction as the reference capacitance sensor element;

a detection module in electrical communication with the operating circuit, wherein the detection module is adapted to receive an electrical signal from the integral capacitance sensor element;

a processor module communicatively coupled to the detection module and the computer-readable medium, wherein the processor module is adapted to:
obtain the capacitance (Cᵤₙₖ) of the integral capacitance sensor element while exposed to an unknown concentration of a specified analyte vapor for which a corresponding reference correlation exists in the calibration library;
obtain the baseline capacitance (C_{int base}) for the integral capacitance sensor element;
obtain a relative capacitance (C_{unk rel})=(Cᵤₙₖ−C_{int base})/C_{int base};
compare C_{unk rel} to a corresponding reference correlation in the reference library and obtain the true concentration of the analyte vapor; and
   at least one of:
      record the true concentration to the computer readable medium; or
      communicate the true concentration to a display member; and

a communication interface module communicatively coupled to the display member and the processor module,

wherein the operating circuit supplies electrical power to at least the detection module, processor module, display member, and communication interface module.

In some embodiments, the electronic device further comprises an integral capacitance sensor element in electrical communication with the operating circuit, wherein the integral capacitance sensor element is of the same construction as reference capacitance sensor element.

In another aspect, the present disclosure provides a method of making a calibrated electronic sensor, the method comprising:
providing an electronic device according to the present disclosure;
obtaining the baseline capacitance (C_{int base}) for the integral capacitance sensor element by a method comprising:
   exposing the integral sensor element to a known first vapor concentration of the first analyte, wherein the integral sensor element comprises a layer of microporous material disposed between and contacting two electrodes, and wherein at least a portion of the second analyte is adsorbed within pores of the microporous material;
   measuring a first capacitance (C_{int meas1}) of the integral sensor element while the integral sensor element is exposed to a known first vapor concentration of the second analyte;
   obtaining a first relative reference capacitance (C_{n1 ref1}) of a reference sensor element at the first vapor concentration of the first analyte;
   calculating C_{int base} as C_{int meas1}/(1±C_{n1 ref1}); and

storing C_{int base} on the electronic device to provide the calibrated electronic sensor.

In yet another aspect, the present disclosure provides a calibrated electronic sensor prepared according to the present disclosure.

In yet another aspect, the present disclosure provides a method of using a calibrated electronic sensor, the method comprising:

providing a calibrated electronic sensor according to the present disclosure;

measuring a capacitance (Cᵤₙₖ) of the integral capacitance sensor element while exposed to the unknown concentration of the specified analyte vapor at the standard temperature;

obtaining a relative capacitance (C_{unk rel})=(Cᵤₙₖ−C_{int base})/C_{int base};

comparing C_{unk rel} to a corresponding reference correlation in the reference library and obtaining the true concentration of the analyte vapor; and

at least one of:
recording the true concentration of analyte vapor to the computer readable medium; or
communicating the true concentration of the analyte vapor to the display member.

Advantageously, the present disclosure provides substantial improvement in the time and effort required for calibration of absorptive capacitance sensors, either during manufacture or by an end-user. In addition, correction for humidity is easily accomplished according to the present disclosure.

Since porosity of absorptive layer, electrode area, and absorptive layer thickness are not significantly involved in converting capacitance to concentration using techniques according to the present disclosure, sophisticated manufacturing process are not required to control those parameters very precisely. For example, according to the present disclosure, it is not necessary to coat the absorptive layer very uniformly. Further, the electrode area need not be particularly consistent, which allows more flexibility in manufacturing methods used.

Steps recited in processes of the present disclosure, including the claims, can be carried out in any suitable order, unless otherwise specified.

As used herein:

the term “baseline capacitance” refers to the capacitance that would be observed in the absence of an analyte vapor under the same conditions;

the term “permeable” in reference to a layer of a material means that in areas, wherein the layer is present, the layer is sufficiently porous to be non-reactively permeable through its thickness (e.g., at 25° C.) by at least one organic compound;

the term “reference correlation” refers to a correlation between two a capacitance value and the concentration of an analyte, which correlation may be, for example, mathematical, tabular, and/or graphical; and

the term “true capacitance” refers to the observed capacitance minus the baseline capacitance.

The features and advantages of the present disclosure will be further understood upon consideration of the detailed description as well as the appended claims.

### BRIEF DESCRIPTION OF THE DRAWINGS

FIG. 1A is a plot of true capacitance for 16 sensors exposed to 100 ppm MEK vapor and to 25 ppm toluene vapor.

FIG. 1B is a plot of true capacitance for 16 sensors exposed to 25 parts per million by weight (ppm) of toluene vapor divided by the true capacitance of the sensor when exposed to 25 ppm of methyl ethyl ketone (MEK) vapor.

FIG. 2 depicts plots of relative capacitance versus analyte concentration for various organic vapors.

FIG. 3A is a schematic plan view of an exemplary electronic device 300 according to the present disclosure; and

FIG. 3B is an enlarged cross-sectional schematic view of integral capacitance sensor element 310 shown in FIG. 3A.

In all cases, the disclosure is presented by way of representation and not limitation. It should be understood that numerous other modifications and embodiments can be devised by those skilled in the art, which fall within the scope and spirit of the principles of the disclosure.

### DETAILED DESCRIPTION

Capacitance sensor elements referred to in the present disclosure comprise a layer of dielectric microporous material disposed between and contacting first and second conductive electrodes. Analyte vapor is absorbed within pores of the dielectric microporous material causing a change in dielectric constant of the layer of dielectric microporous material, resulting in a change in capacitance of the sensor element.

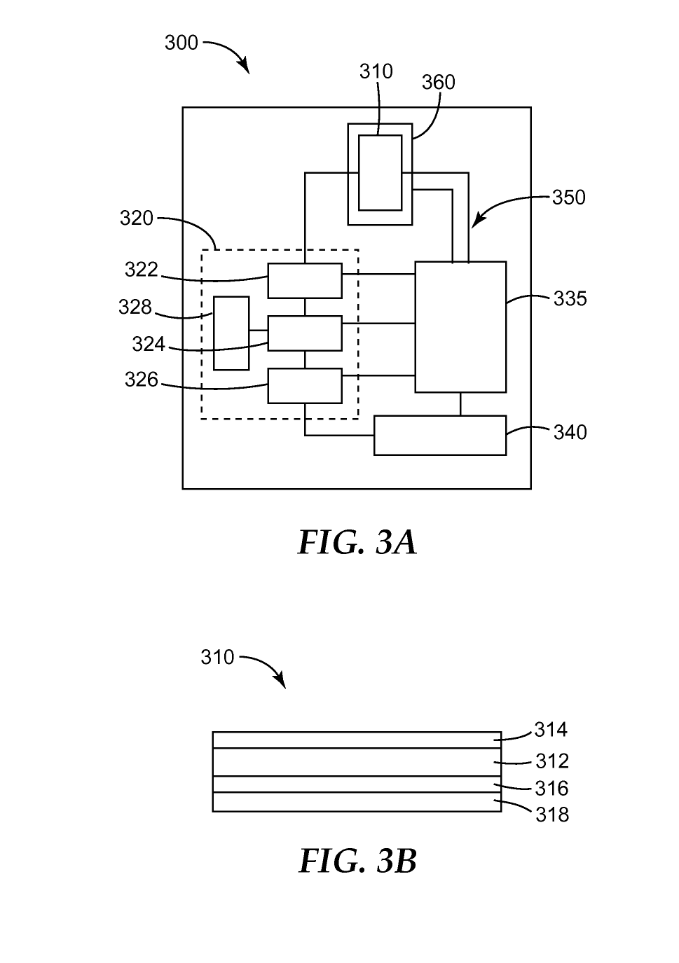

Referring now to FIG. 3B, an exemplary such capacitance sensor element 310 comprises a layer of absorptive intrinsically porous material 312 disposed between and contacting (e.g., sandwiched between) first and second conductive electrodes 316, 314. First conductive electrode 316 is disposed on optional dielectric substrate 318. In the embodiment shown in FIG. 3B, at least the second electrode 314 is permeable by analyte vapors with which the sensor element is intended to be used. For example, in the configuration as shown in FIG. 3B, the second electrode is desirably porous (including microporous) in order to facilitate rapid absorption by the absorptive intrinsically porous material.

In an alternative configuration, the first and second electrodes may be disposed side by side on the surface of a dielectric substrate (e.g., within a single plane), separated by the absorptive intrinsically porous material. In this embodiment, the second conductive electrode may not be permeable by the analyte vapor. In such a case, the second conductive electrode may be fabricated using a material suitable for use as the first conductive electrode.

The dielectric microporous material can be any material that is microporous and is capable of absorbing at least one analyte within its interior. In this context, the terms “microporous” and “microporosity” mean that the material has a significant amount of internal, interconnected pore volume, with the mean pore size (as characterized, for example, by sorption isotherm procedures) being less than about 100 nanometers (nm), typically less than about 10 nm. Such microporosity provides that molecules of organic analyte (if present) will be able to penetrate the internal pore volume of the material and take up residence in the internal pores. The presence of such analyte in the internal pores can alter the dielectric properties of the material such that a change in the dielectric constant (or any other suitable electrical property) can be observed. In some embodiments, the dielectric microporous material comprises a so-called Polymer of Intrinsic Microporosity (PIM). PIMs are polymeric materials with nanometer-scale pores due to inefficient packing of the polymer chains. For example, in Chemical Communications, 2004, (2), pp. 230-231, Budd et al. report a series of intrinsically microporous materials containing dibenzodioxane linkages between rigid and/or contorted monomeric building blocks. Representative members of this family of polymers include those generated by condensation of Component A (e.g., A1, A2, or A3) with Component B (e.g., B1, B2, or B3) as shown in Table 1 according to Scheme 1 (below).

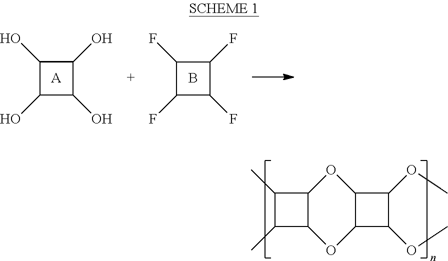

TABLE 1

| COMPONENT A | COMPONENT B |
|---|---|
| 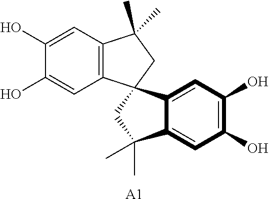 | 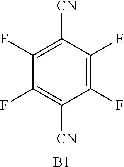 |
| 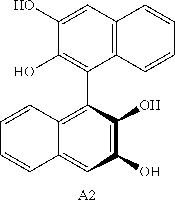 | 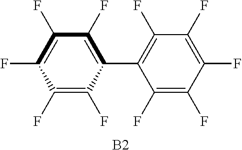 |
| 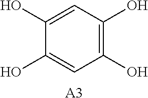 | 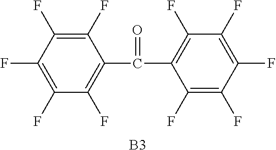 |

Further suitable Components A and B, and resultant intrinsically microporous polymers, are known in the art, for example, as reported by Budd et al. in Journal of Materials Chemistry, 2005, Vol. 15, pp. 1977-1986; by McKeown et al. in Chemistry, A European Journal, 2005, Vol. 11, pp. 2610-2620; by Ghanem et al. in Macromolecules, 2008, vol. 41, pp. 1640-1646; by Ghanem et al. in Advanced Materials, 2008, vol. 20, pp. 2766-2771; by Carta et al. in Organic Letters, 2008, vol. 10(13), pp. 2641-2643; in PCT Published Application WO 2005/012397 A2 (McKeown et al.); and in U.S. Patent Appl. Publ. No. 2006/0246273 (McKeown et al.), the disclosure of which is incorporated herein by reference. Such polymers can be synthesized, for example, by a step-growth polymerization where a bis-catechol such as, e.g., A1 (5,5′,6,6′-tetrahydroxy-3,3,3′,3′-tetramethyl-1,1′-spirobisindane) is allowed to react with a fluorinated arene such as, e.g., B1 (tetrafluoroterephthalonitrile) under basic conditions. Due to the rigidity and contorted nature of the backbone of the resulting polymers, these polymers are unable to pack tightly in the solid state and thus have at least 10 percent free volume and are intrinsically microporous.

PIMs may be blended with other materials. For example, a PIM may be blended with a material that itself is not an absorptive dielectric material. Even though not contributing to an analyte response, such a material may be useful for other reasons. For example, such a material may allow the formation of a PIM-containing layer which has superior mechanical properties and the like. In one embodiment, PIMs may be dissolved in a common solvent with the other material to form a homogeneous solution, which may be cast to form an absorptive dielectric blend layer comprising both the PIM and the other polymer(s). PIMs may also be blended with a material that is an absorptive dielectric material (for example, zeolites, activated carbon, silica gel, hyper-crosslinked polymer networks and the like). Such materials may comprise insoluble materials that are suspended in a solution comprising of a PIMs material. Coating and drying of such a solution/suspension may provide a composite absorptive dielectric layer comprising both the PIM material and the additional absorptive dielectric material.

PIMs are typically soluble in organic solvents such as, for example, tetrahydrofuran and can thus be cast as films from solution (e.g., by spin-coating, dip coating, or bar coating). However, characteristics (accessible thicknesses, optical clarity, and/or appearance) of films made from solutions of these polymers may vary markedly depending on the solvent or solvent system used to cast the film. For example, intrinsically microporous polymers of higher molecular weights may need to be cast from relatively unusual solvents (e.g., cyclohexene oxide, chlorobenzene, or tetrahydropyran) to generate films with desirable properties for use in optochemical sensors as described herein. In addition to solution coating methods, the detection layer may be coated onto to the first conductive electrode by any other suitable method.

After a PIM is deposited (e.g., coated) or otherwise formed so as to comprise an absorptive dielectric layer, the material may be crosslinked using a suitable crosslinking agent such as, for example, bis(benzonitrile)palladium(II) dichloride. This process may render the absorptive dielectric layer insoluble in organic solvents, and/or may enhance certain physical properties such as durability, abrasion resistance, etc., which may be desirable in certain applications.

PIMs may be hydrophobic so that they will not absorb liquid water to an extent that the material swells significantly or otherwise exhibits a significant change in a physical property. Such hydrophobic properties are useful in providing an organic analyte sensor element that is relatively insensitive to the presence of water. The material may however comprise relatively polar moieties for specific purposes.

In one embodiment, the dielectric microporous material comprises a continuous matrix. Such a matrix is defined as an assembly (e.g., a coating and/or a layer) in which the solid portion of the material is continuously interconnected (irrespective of the presence of porosity as described above, or of the presence of optional additives as discussed below). That is, a continuous matrix is distinguishable from an assembly that comprises an aggregation of particles (e.g., zeolites, activated carbons, and carbon nanotubes). For example, a layer or coating deposited from a solution will typically comprise a continuous matrix (even if the coating itself is applied in a patterned manner and/or comprises particulate additives). A collection of particles deposited via powder spraying, coating and drying of a dispersion (e.g., a latex), or by coating and drying of a sol-gel mixture, may not comprise a continuous network. However, if such a latex or sol-gel layer can be consolidated such that individual particles are no longer discernible, nor is it possible to discern areas of the assembly that were obtained from different particles, such a layer may then be considered to be a continuous matrix.

The absorptive dielectric material may have any thickness, but typically is in a range of from 150 nm to 1200 nm. More typically, the absorptive dielectric material forms a layer having a thickness in a range of from 500 nm to 900 nm, although thinner and thicker detection layers may also be used.

The absorptive layer may contain additives such as fillers, antioxidants, light stabilizers in addition to the PIM material, but since they may tend to interfere with proper operation of the sensor element such additives are typically minimized or not present. Combinations of PIM materials may be used.

In various embodiments, an additional layer or layers of material that is not an absorptive dielectric material may be provided in proximity to the absorptive dielectric layer. Such a layer or layers may be provided for any of a variety of reasons; for example, as a protective layer or as a tie layer to improve adhesion.

In various embodiments, multiple individual layers of absorptive dielectric material can be used. For example, multiple layers of PIM materials can be used. Alternatively, one or more layers of some other absorptive dielectric material can be used in addition to a layer of PIM material. The various layers of absorptive dielectric material can be in direct contact with each other; or, they can be separated by a layer or layers present for some other purpose (e.g., passivation layers, tie layers, as described herein).

The first conductive electrode can comprise any suitable conductive material. Combinations of different materials (conductive and/or nonconductive) can be used, as different layers or as a mixture, as long as sufficient overall conductivity is provided, Typically, the first conductive electrode has a sheet resistance of less than about 10⁷ ohms/square. Examples of materials that can be used to make the first conductive electrode organic materials, inorganic materials, metals, alloys, and various mixtures and composites comprising any or all of these materials. In certain embodiments, coated (for example, thermal vapor coated, sputter coated, etc.) metals or metal oxides, or combinations thereof, may be used. Suitable conductive materials include for example aluminum, nickel, titanium, tin, indium-tin oxide, gold, silver, platinum, palladium, copper, chromium, and combinations thereof.

The first conductive electrode can be of any thickness as long as it is conductive; for example, in a thickness in a range of from at least 4 nm to 400 nm, or from 10 nm to 200 nm For example, the first conductive electrode may have sufficient thickness to be self-supporting (e.g., in a range of from 10 micrometers to one centimeter), although greater and lesser thicknesses may also be used.

The second conductive electrode may include additional components as long as it remains permeable by at least one organic analyte. Examples of materials that can be used to make the second conductive electrode include organic materials, inorganic materials, metals, alloys, and various mixtures and composites comprising any or all of these materials. In certain embodiments, coated (for example, thermal vapor coated, sputter coated, etc.) metals or metal oxides, or combinations thereof, may be used. Suitable conductive materials include for example aluminum, nickel, titanium, tin, indium-tin oxide, gold, silver, platinum, palladium, copper, chromium, carbon nanotubes, and combinations thereof. Details concerning silver ink coated porous conductive electrodes can also be found in PCT International Publication No. WO 2009/045733 A2 (Gryska et al.). Details concerning vapor-deposited vapor-permeable conductive electrodes can also be found in U.S. Provisional Patent Appln. No. 61/388,146 (Palazzotto et al.), the disclosure of which is incorporated herein by reference.

Combinations of different materials (conductive and/or nonconductive) can be used, as different layers or as a mixture, as long as sufficient overall conductivity and permeability is provided. Typically, the second conductive electrode has a sheet resistance of less than about 10⁷ ohms/square.

The second conductive electrode typically has a thickness in a range of from 1 nanometer (nm) to 500 nm, although other thicknesses may be used. For example, in some embodiments the second conductive electrode may have a thickness in a range of from 1 nm to 200 nm, from 1 nm to 100 nm, from 1 nm to 10 nm, or even from 1 nm to 5 nm. Greater thicknesses may have undesirably low levels of permeability, while lesser thicknesses may become insufficiently conductive and/or difficult to electrically connect to the second conductive member. Since the second conductive electrode is permeable, the first conductive electrode typically comprises a continuous, uninterrupted layer, but it may contain openings or other interruptions if desired.

Referring again to FIG. 3B, optional dielectric substrate 318 may be, for example, a continuous slab, layer or film of material that is in proximity to the first conductive electrode, and which may serve to provide physical strength and integrity to the sensor element 310. Any solid dielectric material having structural integrity, flexible or rigid, may be used, subject to type of sensor element. Suitable dielectric materials may be used, including, for example, glass, ceramic, and/or plastic. In large scale production, a polymeric film (such as polyester or polyimide) may be used.

An optional protective cover or barrier layer can be provided in proximity to at least one of the first or second conductive electrodes. For example, in one embodiment, a cover layer can be placed atop the second conductive electrode, leaving an area of second conductive electrode accessible for electrical contact with the second conductive member electrical contact. Any such cover layer should not significantly interfere with the functioning of sensor element. For example, if the sensor element is configured such that an analyte of interest must pass through cover layer in order to reach the absorptive dielectric layer, the cover layer should be sufficiently permeable by the analyte.

Further details concerning fabrication of absorptive capacitance sensor elements including PIMs, and principles of their operation, can be found in, for example, U.S. Patent Appl. Publ. Nos. 2011/0045601 A1 (Gryska et al.) and 2011/0031983 A1 (David et al.), and U.S. Provisional Appln. No. 61/388,146, (Palazzotto et al.), the disclosures of which are incorporated herein by reference. Further details concerning an absorptive capacitance sensor element wherein the dielectric microporous material is an organosilicate material is described in PCT Publication No. WO 2010/075333 A2 (Thomas). Various designs (e.g., interdigitated electrode or parallel electrode) of absorptive capacitance sensor element are known and suitable for practice of the present disclosure.

Upon absorption of sufficient analyte by the absorptive dielectric layer, a detectable change in an electrical property associated with the sensor element (including but not limited to, capacitance, impedance, admittance, current, or resistance) may occur. Such a detectable change may be detected by an operating circuit that is in electrical communication with the first and second conductive electrodes. In this context, “operating circuit” refers generally to an electrical apparatus that can be used to apply a voltage to the first conductive electrode and the second conductive electrode (thus imparting a charge differential to the electrodes), and/or to monitor an electrical property of the sensor element, wherein the electrical property may change in response to the presence of an organic analyte. In various embodiments, the operating circuit may monitor any or a combination of inductance, capacitance, voltage, resistance, conductance, current, impedance, phase angle, loss factor, or dissipation.

Such an operating circuit may comprise a single apparatus which both applies voltage to the electrodes, and monitors an electrical property. In an alternative embodiment, such an operating circuit may comprise two separate apparatuses, one to provide voltage, and one to monitor the signal. The operating circuit is typically electrically coupled to first conductive electrode and to second conductive electrode by conductive members.

As discussed above, the present inventor has discovered that, for absorptive capacitance sensors of the type discussed above, the ratio of the first true capacitance (C1) obtained at a fixed concentration of a first vapor to a second true capacitance (C2) obtained using a fixed concentration of a second vapor (i.e., C1/C2) is substantially constant for capacitance sensors of similar design; for example, as produced according to a manufacturing process using the same materials.

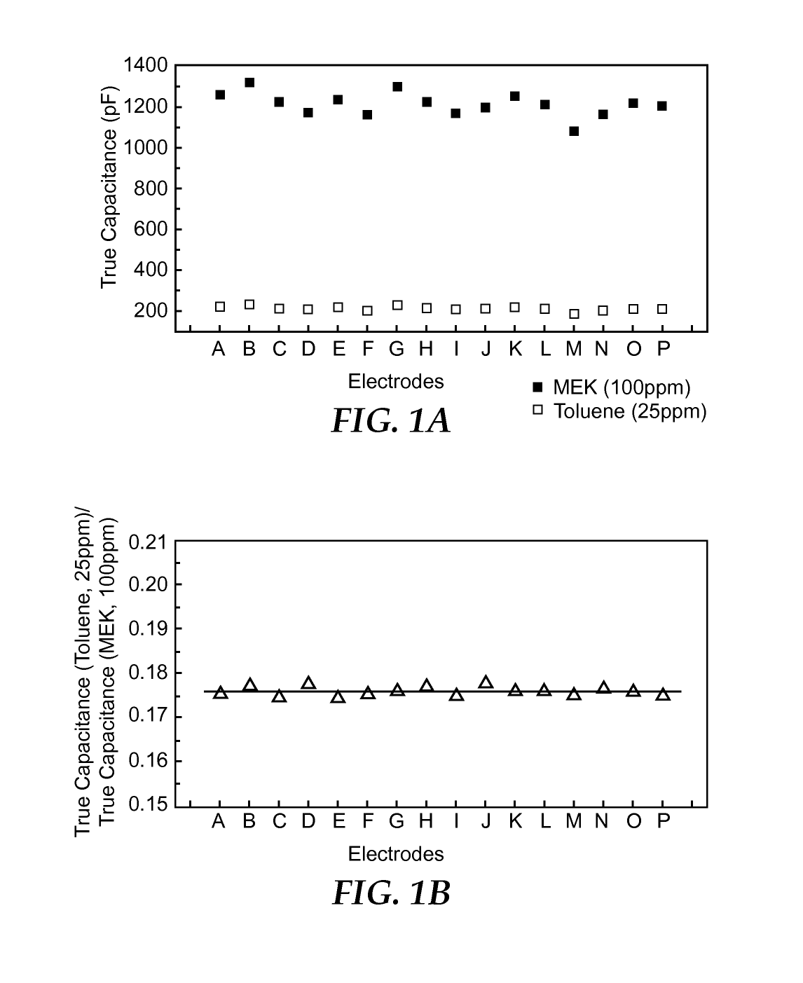

FIG. 1A reports true capacitance values obtained on exposure to 100 parts per million (ppm) methyl ethyl ketone (MEK) vapor and exposure to 25 ppm toluene vapor (under standard conditions using dry air and a sensor element temperature of about 23° C.) using 16 different absorptive capacitance sensors prepared as described in the Examples hereinbelow.

Due to random variation, each sensor had a slightly different electrode configuration and from the others, resulting in different true capacitance obtained on exposure to 100 parts per million (ppm) of methyl ethyl ketone (MEK) vapor and exposure to 25 ppm of toluene vapor. Yet, as can be seen in FIG. 1B the ratio of true capacitance obtained on exposure to 25 ppm toluene vapor exposure to that obtained on exposure to 100 ppm of MEK exposure was substantially constant.

Accordingly, methods of generating a calibration library that exploits the above discovery will be discussed below in the context of capacitance sensor elements operating under standard temperature and humidity conditions (e.g., using dry air in combination with analyte vapor) unless otherwise indicated. It is generally important to use a standard temperature in making capacitance measurements according to the present disclosure, as there is typically a temperature dependence to the observed capacitance of the capacitance sensor elements. Since using ambient temperature may result in temperature fluctuation, it is desirable to use a standard temperature that is above ambient (e.g., about 23° C.) so that constant temperature will be easily achieved in the vast majority of use conditions. For example, the temperature may be achieved by heating the capacitance sensor element to a set temperature within in a range of from 30° C. to 100° C., from 40° C. to 80° C., from 50° C. to 65° C., or even about 55° C., although higher and lower temperatures (including temperatures below ambient) may also be used if desired. Heating may be accomplished by any suitable method, including, for example, resistance heater elements. An exemplary configuration wherein the first conductive electrode also serves as a heating element is described in co-pending U.S. Provisional patent application Ser. No. ______ (Attorney Docket No. 67486US002) entitled “VAPOR SENSOR INCLUDING SENSOR ELEMENT WITH INTEGRAL HEATING”, concurrently filed herewith, the disclosure of which is incorporated herein by reference.

The reference capacitance sensor element comprises a layer of dielectric microporous material disposed between and contacting first and second conductive electrodes, and at least a portion of the analyte vapor is absorbed within pores of the dielectric microporous material.

### General Method for Generating a Reference Library

The following discussion pertains to a generally applicable method of generating a calibration library.

In a step a), the capacitance (C_{ref}) of a reference capacitance sensor element is measured while exposed to a known concentration (Y) of a first analyte vapor. The choice of analyte is not particularly limited provided that the analyte has at least some vapor pressure under measuring conditions, and is reversibly absorbable in the layer of dielectric microporous material. Typically, the analyte is a volatile organic compound; however, this is not a requirement. Examples of suitable analyte vapors include aliphatic hydrocarbons (e.g., n-octane or cyclohexane), ketones (e.g., acetone or methyl ethyl ketone), aromatic hydrocarbons (benzene, toluene, chlorobenzene, or naphthalene), nitriles (e.g., acetonitrile or benzonitrile), chlorinated aliphatic hydrocarbons (e.g., chloroform, dichloroethane, methylene chloride, carbon tetrachloride, or tetrachloroethylene), esters (e.g., vinyl acetate, ethyl acetate, butyl acetate, or methyl benzoate), sulfides (e.g., phenyl mercaptan), ethers (e.g., methyl isobutyl ether or diethyl ether, aldehydes (e.g., formaldehyde, benzaldehyde, or acetaldehyde), alcohols (e.g., methanol or ethanol), amines (e.g., 2-aminopyridine), organic acids (e.g., acetic acid, propanoic acid), isocyanates (e.g., methyl isocyanate or toluene-2,4-diisocyanate), and nitro-substituted organics (e.g., nitromethane or nitrobenzene).

In a step b), the baseline capacitance (C_{ref base}) of the reference capacitance sensor element is measured in the absence of the first analyte vapor at the standard temperature. This second step may be carried out prior to or after step a).

In a step c), the true reference capacitance (C_{ref true}) is determined. For example, C_{ref true} can be determined by subtracting C_{ref base} from C_{ref}. However, any other method of determining an equivalent value of C_{ref true} may also be used.

In a step d), the capacitance (Cₙ₂) of the reference capacitance sensor element is determined while exposed to a known concentration of a second analyte vapor under the standard conditions.

In a step e), a first relative reference capacitance (C_{u2 ref}) is determined For example, C_{n2 ref} can be determined by subtracting C_{ref base} from Cₙ₂ and dividing the result by C_{ref true}. However, any other method of determining an equivalent value of C_{ref true} may also be used.

In a step f), steps d) and e) are repeated at at least two additional different concentrations of the second analyte vapor, resulting in two additional relative capacitances at known concentrations. For example, d) and e) may be repeated at different concentrations of the second analyte vapor at least 3, at least 4, at least 5, at least 10, at least 20 times, or more. From this information, a reference correlation can be determined between the relative reference capacitance and concentration for a given vapor.

In a step g), a first reference correlation between C_{n2 ref} and the concentration of the second analyte vapor is determined. The correlation may be, for example, a simple look-up table, or a mathematical relationship (e.g., C_{n2 ref} as a function of the concentration of the second analyte vapor) obtained, for example, using curve-fitting analysis. Methods of curve-fitting are well known in the art.

Continuing in like manner using the method described above, it is readily possible to generate reference correlations for any solvent that has a vapor pressure and is absorbed by the microporous material.

In a step h), the first reference correlation, and optionally additional reference correlations, is/are recorded onto a computer-readable medium (i.e., a non-transitory medium). Exemplary computer readable media include electronic computer addressable memory devices such as magnetic disks, tapes, optical disks, read-only semiconductor memory (e.g., ROM), and non-volatile semiconductor (flash) memory (e.g., NAND RAM and EEPROM).

As discussed hereinabove, it is presently discovered that the ratio of true capacitance to the baseline capacitance is essentially constant for many absorptive capacitance sensors of the type described herein. In such a case, a simplified special method for generating a reference library may be used.

### Special Method of Generating a Reference Library

The special method includes the following steps.

In a step a), the capacitance (Cₙ₁) of a reference capacitance sensor element is measured while exposed to a known concentration (Y) of a first analyte vapor at standard temperature.

In a step b), the baseline capacitance (C_{ref base}) of the reference capacitance sensor element is measured in the absence of the first analyte vapor at the standard temperature.

Steps a) and b) are essentially the same as in the General Method of Generating a Reference Library described above.

In a step c), a relative reference capacitance (C_{n1 ref}) is determined C_{n1 ref} may be calculated according to the equation C_{n1 ref}=(Cₙ₁−C_{ref base})/C_{ref base}.

In a step d), steps a) and c) are repeated at at least two (e.g., at least 2, 3, 4, 5, 10, or even at least 20) additional different concentrations of the first analyte vapor.

From the measured relative reference capacitance values at different concentrations of the first analyte vapor, a reference correlation between C_{n1 ref} and the concentration of the first analyte vapor can be constructed (e.g., as described in relation to step g) of the General Method of Generating a Reference Library, described hereinabove.

Accordingly, in a step e) a first reference correlation between C_{n1 ref} and the concentration of the first analyte vapor is generated, and recorded onto a computer-readable medium in a second step f).

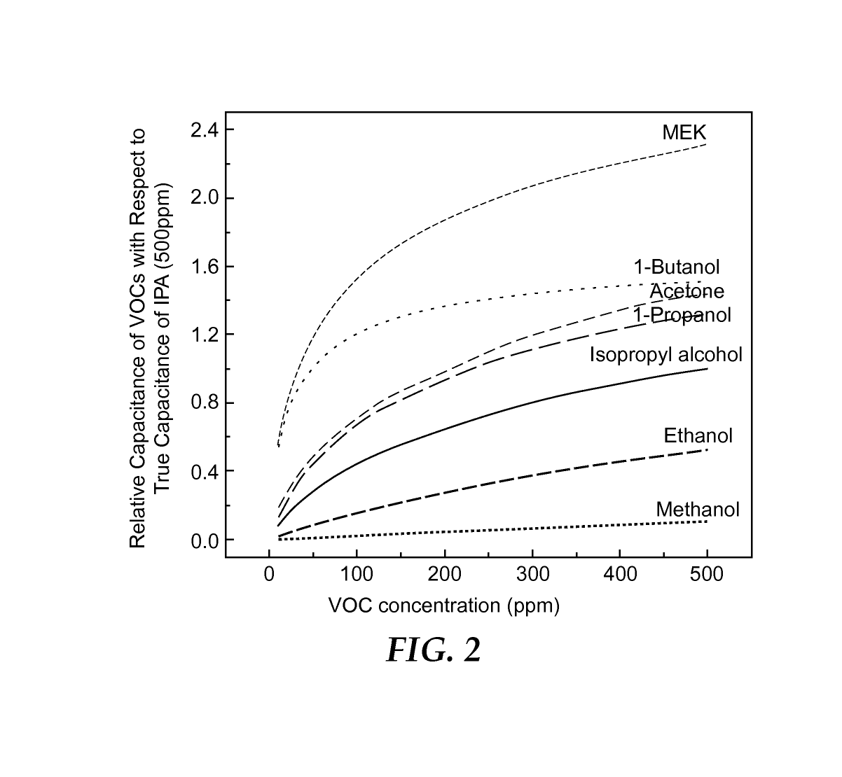

FIG. 2 shows exemplary reference correlations for absorptive capacitance sensor elements as in FIGS. 1A and 1B for various organic vapors after calculating relative capacitance value with respect to the capacitance value from 500 ppm isopropanol (IPA) exposure (i.e., after dividing the measured true capacitance for a given concentration of an organic vapor divided by the true capacitance of the sensor element at 500 ppm IPA exposure).

The above methods of generating a calibration library can be carried out whether or not the first and second analytes are the same or different. Reference correlations for additional analytes can be readily generated by repeating the above procedure using corresponding additional analytes. In some embodiments, methods according to the present disclosure can be used to measure humidity; for example, if at least the second (or a subsequent) analyte is water vapor.

Reference libraries as described above contain reference correlations for various analyte vapors that a sensor element may be used to detect. Accordingly, the computer readable medium can be incorporated into an electronic device.

An exemplary such device is shown in FIG. 3. Referring now to FIG. 3, electronic device 300 comprises operating circuit 350 adapted to power the electrical components included in electronic device 300. Optional integral capacitance sensor element 310 is of substantially the same design as the reference capacitance sensor element used to generate the reference library on computer readable medium 328 which has information stored thereon. The information comprises a calibration library prepared according to a corresponding method of the present disclosure. Detection module 322 is in electrical communication with operating circuit 350, and is adapted receive an electrical signal from optional integral capacitance sensor element 310. Examples of suitable detection modules include analog to digital converters. Processor module 324 is communicatively coupled to detection module 322 and the computer readable medium 328. Examples of suitable processor modules include computer chip processors capable of receiving input information from a computer-readable medium and performing mathematical computations thereby generating output information.

Processor module 324 is adapted to obtain the capacitance (Cᵤₙₖ) of optional integral capacitance sensor element 310 while exposed to an unknown concentration of a specified analyte vapor for which a corresponding reference correlation exists in the calibration library. The capabilities of the processor module will depend on the nature of the correlations contained in the reference library.

For example, if the reference library is generated according to the General Method for Generating a Reference Library described hereinabove, then processor module 324 is further adapted to: obtain the baseline capacitance (C_{int base}) for the optional integral capacitance sensor element 310 (for optional integral capacitance sensor element 310 (e.g., from detection module 322); obtain a relative capacitance C_{unk rel}=(Cᵤₙₖ−C_{int base})/R_{conv}, and compare C_{unk rel} to a corresponding reference correlation in the reference library to obtain the true concentration of the analyte vapor; and record the true concentration to computer readable medium 328, and/or communicate the true concentration to display member 340. R_{conv} is obtainable by a method comprising: exposing the integral sensor element to a known first vapor concentration of the second analyte; measuring a first capacitance (C_{int meas1}) of the integral sensor element while the integral sensor element is exposed to a known first vapor concentration of the second analyte; measuring a second capacitance (C_{int meas2}) of the integral sensor element while the integral sensor element is exposed to a known second vapor concentration of the second analyte; obtaining a difference (ΔC_{int meas}), wherein ΔC_{int meas}=|C_{int meas1}−C_{int meas2}|; obtaining a difference (ΔC_{n2 ref}) between a first relative reference capacitance (C_{n2 ref1}) of a reference sensor element at the first vapor concentration of the second analyte and a second relative reference capacitance (C_{n2 ref2}) of the reference sensor element at the second vapor concentration of the analyte, wherein ΔC_{n2 ref}=|C_{n2 ref1}−C_{n2 ref2}|; and calculating R_{conv} as ΔC_{int meas}/ΔC_{n2 ref}.

However, if the reference library is generated according to the Special Method for Generating a Reference Library described hereinabove, then processor module 324 is further adapted to: obtain the baseline capacitance (C_{int base}) for optional integral capacitance sensor element 310 (e.g., from detection module 322); obtain a relative capacitance (C_{unk rel})=(Cᵤₙₖ−C_{int base})/C_{int base}; compare C_{unk rel} to a corresponding reference correlation in the reference library and obtain the true concentration of the specified analyte vapor (e.g., if acetone is the specified analyte vapor, then the corresponding reference correlation would pertain to acetone); and record the true concentration to computer readable medium 328, and/or communicate the true concentration to display member 340.

Examples of suitable display members include light emitting diode (LED) displays and printers. Communication interface module 326 is communicatively coupled to display member 340 and the processor module 324. Operating circuit 350 includes optional power supply 335 is adapted to provide electrical power to operating circuit 350, detection module 322, integral capacitance sensor element 310, processor module 324, and communication interface module 326. In some embodiments, detection module 322, computer-readable medium 328, processor module 324, and communication interface module 326 are all incorporated into a single semiconductor computer chip 320.

In some embodiments, operating circuit 350 is in electrical communication with an optional heating element 360 (e.g. a resistive heater) that is adapted to heat optional integral capacitance sensor element 310.

While integral capacitance sensor element 310 is optional with respect to the above electronic device 300, it should be included in electronic device 300 prior to use in detecting analyte vapors. Of course, should an integral capacitance sensor element 310 become compromised, it may be replaced by another.

Methods according to the present disclosure can be adapted to account for contributions to capacitance due to humidity (in addition to an organic analyte). Generally, this may be accomplished by calculating water vapor concentration from measured relative humidity and temperature, and comparing it, for example, with a correlation between water vapor concentration and relative capacitance (e.g., as described hereinabove) to determine the relative capacitance due to humidity and then subtracting that from the total relative capacitance observed/calculated due to humidity and analyte. The resulting relative capacitance can then be matched with a corresponding reference correlation of relative capacitance versus the analyte vapor concentration in order to determine it.

Objects and advantages of this disclosure are further illustrated by the following non-limiting examples, but the particular materials and amounts thereof recited in these examples, as well as other conditions and details, should not be construed to unduly limit this disclosure.

### EXAMPLES

Unless otherwise noted, all parts, percentages, ratios, etc. in the Examples and the rest of the specification are by weight.

### Preparation of PIMA (Used for MEK and Toluene Exposures)

In a 2.0 L three-neck round bottomed flask, 33.4365 g of 3,3,3′,3′-tetramethyl-1,1′-spirobisindane-5,5′,6,6′-tetrol (tetrol) and 19.8011 g of tetrafluoroterephthalonitrile (TFTN) were dissolved in 900 mL of anhydrous N,N-dimethylformamide (DMF). The solution was stirred with a mechanical stirrer, and nitrogen was bubbled through the solution for one hour. To this solution was added 81.4480 g of potassium carbonate. The flask was placed in an oil bath at 67° C. The mixture was stirred at this elevated temperature under a nitrogen atmosphere for 67.5 hours. The polymerization mixture was poured into 9.0 L of water. The precipitate formed was isolated by vacuum filtration and washed with 600 mL of methanol. The isolated material was spread out in a pan and allowed to air dry overnight. The solid was placed in a jar and dried under vacuum at 68° C. for 4 hours. The resulting yellow powder was dissolved in 450 mL of tetrahydrofuran. This solution was poured slowly into 9.0 L of methanol. The precipitate formed was isolated by vacuum filtration. The isolated material was spread out in a pan and allowed to air dry overnight. The solid was placed in a jar and dried under vacuum at 68° C. for 4 hours. The precipitation in methanol was performed one more time. The resulting dried, bright yellow polymer weighed 43.21 g. Analysis of the polymer by GPC using light scattering detection showed the material to have a number average molecular weight (Mₙ) of approximately 35,800 g/mol.

### Preparation of PIM B (Used for Generating Reference Correlations)

In an 8-oz (240 mL) amber jar, 5.6161 g of 3,3,3′,3′-tetramethyl-1,1′-spirobisindane-5,5′,6,6′-tetrol (tetrol) and 3.3000 g of tetrafluoroterephthalonitrile (TFTN) were dissolved in 150 mL of anhydrous N,N-dimethylformamide (DMF). To this solution was added 6.0004 g of potassium carbonate. The jar was placed in a laundrometer at 65° C. The mixture was stirred at this elevated temperature for 62 hours. The polymerization mixture was poured into 1.5 L of water. The precipitate formed was isolated by vacuum filtration and washed with 300 mL of methanol. The isolated material was placed in a jar and dried under vacuum at 58° C. for 18 hours. The resulting yellow powder was dissolved in 100 mL of tetrahydrofuran. This solution was poured slowly into 1.5 L of methanol. The precipitate formed was isolated by vacuum filtration. The isolated material was placed in a jar and dried under vacuum at 58° C. for 18 hours. The precipitation in methanol was performed one more time. The resulting dried, bright yellow polymer weighed 7.09 g. Analysis of the polymer by GPC using light scattering detection showed the material to have a number average molecular weight (Mₙ) of approximately 35,600 g/mol.

### Preparation of Sensor Elements

Sensor elements were prepared on 2″×2″ (5.1 cm×5.1 cm) Schott glass slides cut from 440×440 mm panels (1.1 mm thick, D-263 T Standard glass from Schott North America, Elmsford, N.Y.), which were cleaned by soaking them for 30 to 60 minutes in ALCONOX LIQUI-NOX detergent solution (from Alconox, White Plains, N.Y.), then scrubbing each side of the slides with a bristle brush, rinsing them under warm tap water followed by a final rinse with deionized water (DI water). The slides were allowed to air dry covered to prevent dust accumulation on the surface. The dry, clean slides were stored in 7.6 cm wafer carriers obtained from Entegris, Chaska, Minn.

A first conductive electrode was deposited onto the Schott glass slide by e-beam evaporative coating 10.0 nm of titanium (obtained as titanium slug, 9.5 mm×9.5 mm, 99.9+% purity from Alfa Aesar, Ward Hill, Mass.) at a rate of 0.1 nm per second (nm/sec) followed by 150.0 nm of aluminum (obtained as shot, 4-8 mm, Puratronic grade 99.999% from Alfa Aesar) at 0.5 nm/sec using a 2 inches (5 cm)×2 inches (5 cm) square mask (MASK A) having a single rectangular opening with a top border of 0.46 inch (1.2 cm), a bottom border of 0.59 inch (1.5 cm), and left and right borders of 0.14 inch (0.35 cm) prepared from laser-cut 1.16 mm thick stainless steel. All masks were deburred before using to minimize the possibility of shorts caused by sharp edges in the mask. The vapor deposition process was controlled using an INFICON XTC/2 THIN FILM DEPOSITION CONTROLLER from INFICON of East Syracuse, N.Y.

A 4 percent by weight solution of PIM material in chlorobenzene was prepared by mixing the components in a small jar, and placing it on a roller mill overnight or until the polymer was substantially dissolved, then filtering through a one-micron ACRODISC filter (obtained as ACRODISC 25 MM SYRINGE FILTER WITH 1 MICRON GLASS FIBER MEMBRANE from PALL Life Sciences of Ann Arbor, Mich.). The solution was allowed to sit overnight so that any bubbles that formed could escape.

The first conductive electrode was cleaned by placing a specimen (i.e., glass slide with conductive electrode thereon), in a WS-400B-8NPP-LITE SINGLE WAFER spin processor manufactured by Laurell Technologies, Corp. North Wales, Pa., and placing about 0.5 ml of chlorobenzene on the first conductive electrode, then running through a spin coating cycle of 1000 rpm for 1 minute.

The 4 percent by weight solution of PIM material was then coated onto the first conductive electrode under the same spin coating conditions. After spin-coating, PIMS thickness measurements were made using a Model XP-1 Profilometer from AMBiOS Technology of Santa Cruz, Calif. by removing a small section of the coating with an acetone soaked cotton swab. The parameters used in the thickness measurement were a scan speed of 0.1 mm/sec, a scan length of 5 mm, a range of 10 micrometers, a stylus force of 0.20 mg and a filter level of 4. The thickness of the PIM coating generally ranged from 500 to 600 nm. All samples were baked for 1 hour at 100° C. after coating.

A patterned second, silver, electrode was inkjet printed on top of the PIM material according to a pattern that produced a 2×2 array of four 0.60 inch (1.5 cm) height×0.33 inch (0.84 cm) width rectangular ink patches vertically separated by 0.22 inch (0.56 cm) and horizontally separated by 0.48 inch (1.2 cm). In order to inkjet print the second electrode, a bitmap image (702 dots per inch) was created and downloaded to an XY deposition system. The printhead used for depositing a silver nanoparticle sol was a DIMATIX SX3-128 printhead (FUJIFILM Dimatix, Santa Clara, Calif.) with a 10 picoliter drop volume and 128 jets/orifices, the printhead assembly being approximately 6.5 cm long with 508 micron jet to jet spacing. The silver nanoparticle sol used to construct this electrode was obtained from Cabot under the designation AG-IJ-G-100-S1. The silver nanoparticle sol was approximately 15-40 percent by weight ethanol, 15-40 percent by weight ethylene glycol, and 20 percent by weight silver. The sample was held securely during the inkjet printing process by use of a porous aluminum vacuum platen. Upon completion of printing, the sample was removed from the porous aluminum vacuum platen and placed on a hot plate for 15 minutes at 125° C.

After depositing the active electrode, a connecting electrode was prepared by using DGP-40LT-25C, a silver nanoparticle ink from ANP, 244 Buyong industrial complex, Kumho-ri, Buyong-myeon, Chungwon-kun, Chungcheongbuk-do, South Korea. A small artist brush was used to paint a connection to the second conductive electrode to facilitate electrical contact during testing. After painting this connection, the sensors were baked for 1 hour at 150° C. to set the ink

This sensor production process produced a set of 4 sensor elements of approximately 8 mm×10 mm active area (area under the overlapping first and second conductive electrodes that was not covered by the connecting electrode) on an approximately 50 mm×50 mm glass substrate. Individual sensor elements were produced by dicing the sample using a standard glass scoring cutter on the back (inactive side) while supporting the sensor elements so that their front (active) surfaces would not be damaged. After dicing into individual sensor elements, the sensors were stored in 3.81 cm wafer holders from Entegris of Chaska, Minn.

### Capacitance Measurement of Sensors Elements Exposed to Organic Vapors

Before testing, all samples were baked at 150° C. for 1 hour using a convection oven. All tests were performed in air that had been passed over DRIERITE dessicant from W. A. Hammond Co., Ltd., Xenia, Ohio to remove moisture, and activated carbon to eliminate any organic contaminates. The testing chamber allowed the measurement of four sensor specimens at a time. Vapor tests were conducted using a 10 L/minute dry air flow through the system. Various vapor levels were generated using a KD Scientific syringe pump (available from KD Scientific Inc. of Holliston, Mass.) fitted with a 500 microliter gas tight syringe (obtained from Hamilton Company of Reno, Nev.). The syringe pump delivered the organic liquid onto a piece of filter paper suspended in a 500 ml three-necked flask. The flow of dry air past the paper vaporized the solvent. Delivering the solvent at different rates by controlling the syringe pump generated different concentrations of vapor. The syringe pump was controlled by a LABVIEW (software available from National Instruments of Austin, Tex.) program that allowed vapor profiles to be generated during a test run. A MIRAN IR analyzer (available from Thermo Fischer Scientific, Inc., Waltham, Mass.) was used to verify the set concentrations. The capacitance was measured with an LCR meter (available as INSTEK MODEL 821 LCR meter from Instek America, Corp. Chino, Calif.) applying one volt at 1000 Hz across the first and second conductive electrodes. Data was collected and stored using the same LABVIEW program that controlled the syringe pump.

### SELECTED EMBODIMENTS OF THE PRESENT DISCLOSURE

In a first embodiment, the present disclosure provides a method of generating a reference library, the method comprising steps:

a) measuring the capacitance (C_{ref}) of a reference capacitance sensor element while exposed to a known concentration (Y) of a first analyte vapor at standard temperature, wherein the reference capacitance sensor element comprises a layer of dielectric microporous material disposed between and contacting first and second conductive electrodes, and wherein at least a portion of the analyte vapor is absorbed within pores of the dielectric microporous material;

b) measuring the baseline capacitance (C_{ref base}) of the reference capacitance sensor element in the absence of the first analyte vapor at the standard temperature;

c) determining the true reference capacitance C_{ref true}, wherein C_{ref true}=C_{ref}−C_{ref base};

d) measuring the capacitance (Cₙ₂) of the reference capacitance sensor element while exposed to a known concentration of a second analyte vapor;

e) determining a relative reference capacitance (C_{n2 ref}), wherein C_{n2 ref}=(Cₙ₂−C_{ref base})/C_{ref true};

f) repeating steps d) and e) at at least two additional different concentrations of the second analyte vapor;

g) determining a first reference correlation between C_{n2 ref} and the concentration of the second analyte vapor; and

h) recording the first reference correlation onto the computer-readable medium.

In a second embodiment, the present disclosure provides a method of generating a reference library according to the first embodiment, wherein the computer-readable medium comprises a non-transitory semiconductor memory device.

In a third embodiment, the present disclosure provides a method of generating a reference library according to the first or second embodiment, wherein the first analyte vapor and the second analyte vapor are different.

In a fourth embodiment, the present disclosure provides a method of generating a reference library according to any one of the first to third embodiments, wherein the correlation is mathematical.

In a fifth embodiment, the present disclosure provides a method of generating a reference library according to any one of the first to fourth embodiments, wherein the first analyte vapor and the second analyte vapor consist of the same chemical compound.

In a sixth embodiment, the present disclosure provides a method of generating a reference library according to any one of the first to fifth embodiments, wherein the second analyte vapor is water vapor.

In a seventh embodiment, the present disclosure provides a method of generating a reference library according to any one of the first to sixth embodiments, wherein the standard temperature is in a range of from 40° C. to 80° C.

In an eighth embodiment, the present disclosure provides a method of generating a reference library according to any one of the first to seventh embodiments, further comprising:

i) measuring the capacitance (Cₙ₃) of the reference capacitance sensing element while exposed to a known concentration of a third analyte vapor;

j) determining C_{n3 ref}, wherein C_{n3 ref}=(Cₙ₃−C_{ref base})/C_{ref true};

k) repeating steps i) and j) at at least two additional different concentrations of the third analyte vapor;

l) determining a second reference correlation between C_{n3 ref} and the concentration of the third analyte vapor; and

m) recording the second reference correlation onto the computer-readable medium.

In a ninth embodiment, the present disclosure provides an electronic device comprising a computer-readable medium having information stored thereon, the information comprising a reference library prepared according to the method of generating a reference library of any one of the first to eighth embodiments.

In a tenth embodiment, the present disclosure provides an electronic device according to the eighth embodiment, further comprising:

an operating circuit adapted to power at least an integral capacitance sensor element, wherein the integral capacitance sensor element is of substantially the same construction as the reference capacitance sensor element;

a detection module in electrical communication with the operating circuit, wherein the detection module is adapted to receive an electrical signal from the integral capacitance sensor element;

a processor module communicatively coupled to the detection module and the computer-readable medium, wherein the processor module is adapted to:
obtain the capacitance (Cᵤₙₖ) of the integral capacitance sensor element while exposed to an unknown concentration of a specified analyte vapor for which a corresponding reference correlation exists in the calibration library;
obtain the baseline capacitance (C_{int base}) for the integral capacitance sensor element;
obtain a relative capacitance C_{unk rel}=(Cᵤₙₖ−C_{int base})/R_{conv}, wherein
   R_{conv} is obtainable by a method comprising:
      exposing the integral sensor element to a known first vapor concentration of the second analyte, wherein the integral sensor element comprises a layer of microporous material disposed between and contacting two electrodes, and wherein at least a portion of the second analyte is adsorbed within pores of the microporous material;
      measuring a first capacitance (C_{int meas1}) of the integral sensor element while the integral sensor element is exposed to a known first vapor concentration of the second analyte;
      measuring a second capacitance (C_{int meas2}) of the integral sensor element while the integral sensor element is exposed to a known second vapor concentration of the second analyte;
      obtaining a difference (ΔC_{int meas}), wherein

ΔC_{int meas}=|C_{int meas1}−C_{int meas2}|;
obtaining a difference (ΔC_{n2 ref}) between a first relative reference capacitance (C_{n2 ref1}) of a reference sensor element at the first vapor concentration of the second analyte and a second relative reference capacitance (C_{n2 ref2}) of the reference sensor element at the second vapor concentration of the analyte, wherein ΔC_{n2 ref}=|C_{n2 ref1}−C_{n2 ref2}|; and
calculating R_{conv} as ΔC_{int meas}/ΔC_{n2 ref};
compare C_{unk rel} to a corresponding reference correlation in the reference library and obtaining the true concentration of the analyte vapor; and
   at least one of:
      record the true concentration to the computer readable medium; or
      communicate the true concentration to a display member; and

a communication interface module communicatively coupled to the display member and the processor module,

wherein the operating circuit supplies electrical power to at least the detection module, processor module, display member, and communication interface module.

In an eleventh embodiment, the present disclosure provides an electronic device according to the tenth embodiment, wherein the operating circuit is in electrical communication with a heating element adapted to heat the integral capacitance sensor element.

In a twelfth embodiment, the present disclosure provides an electronic device according to the tenth or eleventh embodiment, wherein the electronic device further comprises an integral capacitance sensor element in electrical communication with the operating circuit, wherein the integral capacitance sensor element is of the same construction as reference capacitance sensor element.

In a thirteenth embodiment, the present disclosure provides a method of making a calibrated electronic sensor, the method comprising:
providing an electronic device according to the eleventh or twelfth embodiment;
obtaining the baseline capacitance (C_{int base}) for the integral capacitance sensor element;
obtaining R_{conv} by a method comprising:
   exposing the integral sensor element to a known first vapor concentration of the second analyte, wherein the integral sensor element comprises a layer of microporous material disposed between and contacting two electrodes, and wherein at least a portion of the second analyte is adsorbed within pores of the microporous material;
   measuring a first capacitance (C_{int meas1}) of the integral sensor element while the integral sensor element is exposed to a known first vapor concentration of the second analyte;
   measuring a second capacitance (C_{int meas2}) of the integral sensor element while the integral sensor element is exposed to a known second vapor concentration of the second analyte;
   obtaining a difference (ΔC_{int meas}), wherein

ΔC_{int meas}=|C_{int meas1}−C_{int meas2}|;
obtaining a difference (ΔC_{n2 ref}) between a first relative reference capacitance (C_{n2 ref1}) of a reference sensor element at the first vapor concentration of the second analyte and a second relative reference capacitance (C_{n2 ref2}) of the reference sensor element at the second vapor concentration of the analyte, wherein

ΔC_{n2 ref}=|C_{n2 ref1}−C_{n2 ref2}|;
calculating R_{conv} as ΔC_{int meas}/ΔC_{n2 ref}; and
storing R_{conv} and C_{int base} on the electronic device to provide the calibrated electronic sensor.

In a fourteenth embodiment, the present disclosure provides a calibrated electronic sensor made according to the method of making a calibrated electronic sensor of the thirteenth embodiment.

In a fifteenth embodiment, the present disclosure provides a method of using a calibrated electronic sensor, the method comprising:

providing a calibrated electronic sensor according to the fourteenth embodiment;

measuring a capacitance (Cᵤₙₖ) of the integral capacitance sensor element while exposed to the unknown concentration of the specified analyte vapor at the standard temperature;

obtaining a relative capacitance C_{unk rel}=(Cᵤₙₖ−C_{int base})/R_{conv};

comparing C_{unk rel} to a corresponding reference correlation in the reference library and obtaining the true concentration of the analyte vapor; and

at least one of:
recording the true concentration of analyte vapor to the computer readable medium; or
communicating the true concentration of the analyte vapor to the display member.

In a sixteenth embodiment, the present disclosure provides a method of generating a reference library, the method comprising steps:

a) measuring the capacitance (Cₙ₁) of a reference capacitance sensor element while exposed to a known concentration (Y) of a first analyte vapor at standard temperature, wherein the reference capacitance sensor element comprises a layer of dielectric microporous material disposed between and contacting first and second conductive electrodes, and wherein at least a portion of the analyte vapor is absorbed within pores of the dielectric microporous material;

b) measuring the baseline capacitance (C_{ref base}) of the reference capacitance sensor element in the absence of the first analyte vapor at the standard temperature;

c) determining a relative reference capacitance (C_{n1 ref}), wherein C_{n1 ref}=(Cₙ₁−C_{ref base})/C_{ref base};

d) repeating steps a) and c) at at least two additional different concentrations of the first analyte vapor;

e) determining a first reference correlation between C_{n1 ref} and the concentration of the first analyte vapor; and

f) recording the first reference correlation onto the computer-readable medium.

In a seventeenth embodiment, the present disclosure provides a method of generating a reference library according to the sixteenth embodiment, wherein the computer-readable medium comprises a non-transitory semiconductor memory device.

In an eighteenth embodiment, the present disclosure provides a method of generating a reference library according to the sixteenth or seventeenth embodiment, wherein the correlation is mathematical.

In a nineteenth embodiment, the present disclosure provides a method of generating a reference library according to any one of the sixteenth to eighteenth embodiments, wherein the first analyte vapor is water vapor.

In a twentieth embodiment, the present disclosure provides a method of generating a reference library according to any one of the sixteenth to nineteenth embodiments, wherein the standard temperature is in a range of from 40° C. to 80° C.

In a twenty-first embodiment, the present disclosure provides a method of generating a reference library according to any one of the sixteenth to twentieth embodiments, further comprising:

g) measuring the capacitance (Cₙ₂) of the reference capacitance sensing element while exposed to a known concentration of a second analyte vapor;

h) determining C_{n2 ref}, wherein C_{n2 ref}=(Cₙ₂−C_{ref base})/C_{ref base};

i) repeating steps g) and h) at at least two additional different concentrations of the second analyte vapor;

j) determining a second reference correlation, wherein the second reference correlation comprises a mathematical or graphical correlation between C_{n2 ref} and the concentration of the second analyte vapor; and

k) recording the second reference correlation onto the computer-readable medium.

In a twenty-second embodiment, the present disclosure provides an electronic device comprising a computer-readable medium having information stored thereon, the information comprising a reference library prepared according to the method of generating a reference library according to any one of the sixteenth to twenty-first embodiments.

In a twenty-third embodiment, the present disclosure provides a method of generating a reference library according to the twenty-first embodiment, further comprising:

an operating circuit adapted to power at least an integral capacitance sensor element,

wherein the integral capacitance sensor element is of substantially the same construction as the reference capacitance sensor element;

a detection module in electrical communication with the operating circuit, wherein the detection module is adapted to receive an electrical signal from the integral capacitance sensor element;

a processor module communicatively coupled to the detection module and the computer-readable medium, wherein the processor module is adapted to:
obtain the capacitance (Cᵤₙₖ) of the integral capacitance sensor element while exposed to an unknown concentration of a specified analyte vapor for which a corresponding reference correlation exists in the calibration library;
obtain the baseline capacitance (C_{int base}) for the integral capacitance sensor element;
obtain a relative capacitance (C_{unk rel})=(Cᵤₙₖ−C_{int base})/C_{int base};
compare C_{unk rel} to a corresponding reference correlation in the reference library and obtain the true concentration of the analyte vapor; and
   at least one of:
      record the true concentration to the computer readable medium; or
      communicate the true concentration to a display member; and

a communication interface module communicatively coupled to the display member and the processor module,

wherein the operating circuit supplies electrical power to at least the detection module, processor module, display member, and communication interface module.

In a twenty-fourth embodiment, the present disclosure provides an electronic device according to the twenty third embodiment, wherein the operating circuit is in electrical communication with a heating element adapted to heat the integral capacitance sensor element.

In a twenty-fifth embodiment, the present disclosure provides an electronic device according to the twenty-third or twenty-fourth embodiment, wherein the electronic device further comprises an integral capacitance sensor element in electrical communication with the operating circuit, wherein the integral capacitance sensor element is of the same construction as reference capacitance sensor element.

In a twenty-sixth embodiment, the present disclosure provides a method of making a calibrated electronic sensor, the method comprising:
providing an electronic device according to the twenty-fourth or twenty-fifth embodiment;
obtaining the baseline capacitance (C_{int base}) for the integral capacitance sensor element by a method comprising:
   exposing the integral sensor element to a known first vapor concentration of the first analyte, wherein the integral sensor element comprises a layer of microporous material disposed between and contacting two electrodes, and wherein at least a portion of the second analyte is adsorbed within pores of the microporous material;
   measuring a first capacitance (C_{int meas1}) of the integral sensor element while the integral sensor element is exposed to a known first vapor concentration of the second analyte;
   obtaining a first relative reference capacitance (C_{n1 ref1}) of a reference sensor element at the first vapor concentration of the first analyte;
   calculating C_{int base} as C_{int meas1}/(1+C_{n1 ref1}); and
   storing C_{int base} on the electronic device to provide the calibrated electronic sensor.

In a twenty-seventh embodiment, the present disclosure provides a calibrated electronic sensor made according to the method of making a calibrated electronic sensor of the twenty-sixth embodiment.

In a twenty-eighth embodiment, the present disclosure provides a method of using a calibrated electronic sensor, the method comprising:

providing a calibrated electronic sensor according to the twenty-seventh embodiment;

measuring a capacitance (Cᵤₙₖ) of the integral capacitance sensor element while exposed to the unknown concentration of the specified analyte vapor at the standard temperature;

obtaining a relative capacitance (C_{unk rel})=(Cᵤₙₖ−C_{int base})/C_{int base};

comparing C_{unk rel} to a corresponding reference correlation in the reference library and obtaining the true concentration of the analyte vapor; and

at least one of:
recording the true concentration of analyte vapor to the computer readable medium; or
communicating the true concentration of the analyte vapor to the display member.

Various modifications and alterations of this disclosure may be made by those skilled in the art without departing from the scope and spirit of this disclosure, and it should be understood that this disclosure is not to be unduly limited to the illustrative embodiments set forth herein.

1-28. (canceled)

29. A method of generating a reference library, the method comprising steps:
a) measuring the capacitance (C_{ref}) of a reference capacitance sensor element while exposed to a known concentration (Y) of a first analyte vapor at standard temperature, wherein the reference capacitance sensor element comprises a layer of dielectric microporous material disposed between and contacting first and second conductive electrodes, and wherein at least a portion of the analyte vapor is absorbed within pores of the dielectric microporous material;
b) measuring the baseline capacitance (C_{ref base}) of the reference capacitance sensor element in the absence of the first analyte vapor at the standard temperature;
c) determining the true reference capacitance C_{ref true}, wherein C_{ref true}=C_{ref}−C_{ref base};
d) measuring the capacitance (Cₙ₂) of the reference capacitance sensor element while exposed to a known concentration of a second analyte vapor;
e) determining a relative reference capacitance (C_{n2 ref}), wherein C_{n2 ref}=(Cₙ₂−C_{ref base})/C_{ref true};
f) repeating steps d) and e) at at least two additional different concentrations of the second analyte vapor;
g) determining a first reference correlation between C_{n2 ref} and the concentration of the second analyte vapor; and
h) recording the first reference correlation onto the computer-readable medium.

30. The method of generating a reference library of claim 29, wherein the first analyte vapor and the second analyte vapor are different.

31. An electronic device comprising:
a computer-readable medium having information stored thereon, the information comprising a reference library preparable according to the method of generating a reference library of claim 29;
an operating circuit adapted to power at least an integral capacitance sensor element, wherein the integral capacitance sensor element is of substantially the same construction as the reference capacitance sensor element;
a detection module in electrical communication with the operating circuit, wherein the detection module is adapted to receive an electrical signal from the integral capacitance sensor element;
a processor module communicatively coupled to the detection module and the computer-readable medium, wherein the processor module is adapted to:
obtain the capacitance (Cᵤₙₖ) of the integral capacitance sensor element while exposed to an unknown concentration of a specified analyte vapor for which a corresponding reference correlation exists in the calibration library;
obtain the baseline capacitance (C_{int base}) for the integral capacitance sensor element;
obtain a relative capacitance C_{unk rel}=(Cᵤₙₖ−C_{int base})/R_{conv}, wherein R_{conv} is obtainable by a method comprising:
exposing the integral sensor element to a known first vapor concentration of the second analyte, wherein the integral sensor element comprises a layer of microporous material disposed between and contacting two electrodes, and wherein at least a portion of the second analyte is adsorbed within pores of the microporous material;
measuring a first capacitance (C_{int meas1}) of the integral sensor element while the integral sensor element is exposed to a known first vapor concentration of the second analyte;
measuring a second capacitance (C_{int meas2}) of the integral sensor element while the integral sensor element is exposed to a known second vapor concentration of the second analyte;
obtaining a difference (ΔC_{int meas}), wherein
ΔC_{int meas}=|C_{int meas1}−C_{int meas2}|;
obtaining a difference (ΔC_{n2 ref}) between a first relative reference capacitance (C_{n2 ref1}) of a reference sensor element at the first vapor concentration of the second analyte and a second relative reference capacitance (C_{n2 ref2}) of the reference sensor element at the second vapor concentration of the analyte, wherein
ΔC_{n2 ref}=|C_{n2 ref1}−C_{n2 ref2}|;and
calculating R_{conv} as ΔC_{int meas}/ΔC_{n2 ref};
compare C_{unk rel} to a corresponding reference correlation in the reference library and obtaining the true concentration of the analyte vapor; and
at least one of:
record the true concentration to the computer readable medium; or
communicate the true concentration to a display member; and
a communication interface module communicatively coupled to the display member and the processor module,
wherein the operating circuit supplies electrical power to at least the detection module, processor module, display member, and communication interface module.

32. A method of making a calibrated electronic sensor, the method comprising:
providing an electronic device according to claim 31;
obtaining the baseline capacitance (C_{int base}) for the integral capacitance sensor element;
obtaining R_{conv} by a method comprising:
exposing the integral sensor element to a known first vapor concentration of the second analyte, wherein the integral sensor element comprises a layer of microporous material disposed between and contacting two electrodes, and wherein at least a portion of the second analyte is adsorbed within pores of the microporous material;
measuring a first capacitance (C_{int meas1}) of the integral sensor element while the integral sensor element is exposed to a known first vapor concentration of the second analyte;
measuring a second capacitance (C_{int meas2}) of the integral sensor element while the integral sensor element is exposed to a known second vapor concentration of the second analyte;
obtaining a difference (ΔC_{int meas}), wherein
ΔC_{int meas}=|C_{int meas1}−C_{int meas2}|;
obtaining a difference (ΔC_{n2 ref}) between a first relative reference capacitance (C_{n2 ref1}) of a reference sensor element at the first vapor concentration of the second analyte and a second relative reference capacitance (C_{n2 ref2}) of the reference sensor element at the second vapor concentration of the second analyte, wherein
ΔC_{n2 ref}=|C_{n2 ref1}−C_{n2 ref2}|;
calculating R_{conv} as ΔC_{int meas}/ΔC_{n2 ref}; and
storing R_{conv} and C_{int base} on the electronic device to provide the calibrated electronic sensor.

33. A method of using a calibrated electronic sensor, the method comprising:
providing a calibrated electronic sensor made according to made according to the method of claim 32;
measuring a capacitance (Cᵤₙₖ) of the integral capacitance sensor element while exposed to the unknown concentration of the specified analyte vapor at the standard temperature;
obtaining a relative capacitance C_{unk rel}=(Cᵤₙₖ−C_{int base})/R_{conv};
comparing C_{unk rel} to a corresponding reference correlation in the reference library and obtaining the true concentration of the analyte vapor; and
at least one of:
recording the true concentration of analyte vapor to the computer readable medium; or
communicating the true concentration of the analyte vapor to the display member.

34. A method of generating a reference library, the method comprising steps:
a) measuring the capacitance (Cₙ₁) of a reference capacitance sensor element while exposed to a known concentration (Y) of a first analyte vapor at standard temperature, wherein the reference capacitance sensor element comprises a layer of dielectric microporous material disposed between and contacting first and second conductive electrodes, and wherein at least a portion of the analyte vapor is absorbed within pores of the dielectric microporous material;
b) measuring the baseline capacitance (C_{ref base}) of the reference capacitance sensor element in the absence of the first analyte vapor at the standard temperature;
c) determining a relative reference capacitance (C_{n1 ref}), wherein C_{n1 ref}=(Cₙ₁−C_{ref base})/C_{ref base};
d) repeating steps a) and c) at at least two additional different concentrations of the first analyte vapor;
e) determining a first reference correlation between C_{n1 ref} and the concentration of the first analyte vapor; and
f) recording the first reference correlation onto the computer-readable medium.

35. An electronic device comprising:
a computer-readable medium having information stored thereon, the information comprising a reference library prepared according to the method of generating a reference library of claim 34;
an operating circuit adapted to power at least an integral capacitance sensor element, wherein the integral capacitance sensor element is of substantially the same construction as the reference capacitance sensor element;
a detection module in electrical communication with the operating circuit, wherein the detection module is adapted to receive an electrical signal from the integral capacitance sensor element;
a processor module communicatively coupled to the detection module and the computer-readable medium, wherein the processor module is adapted to:
obtain the capacitance (Cᵤₙₖ) of the integral capacitance sensor element while exposed to an unknown concentration of a specified analyte vapor for which a corresponding reference correlation exists in the calibration library;
obtain the baseline capacitance (C_{int base}) for the integral capacitance sensor element;
obtain a relative capacitance (C_{unk rel})=(Cᵤₙₖ−C_{int base})/C_{int base};
compare C_{unk rel} to a corresponding reference correlation in the reference library and obtain the true concentration of the analyte vapor; and
at least one of:
record the true concentration to the computer readable medium; or
communicate the true concentration to a display member; and
a communication interface module communicatively coupled to the display member and the processor module,
wherein the operating circuit supplies electrical power to at least the detection module, processor module, display member, and communication interface module.

36. The electronic device of claim 35, wherein the operating circuit is in electrical communication with a heating element adapted to heat the integral capacitance sensor element.

37. A method of making a calibrated electronic sensor, the method comprising:
providing an electronic device according to claim 36;
obtaining the baseline capacitance (C_{int base}) for the integral capacitance sensor element by a method comprising:
exposing the integral sensor element to a known first vapor concentration of the first analyte, wherein the integral sensor element comprises a layer of microporous material disposed between and contacting two electrodes, and wherein at least a portion of the second analyte is adsorbed within pores of the microporous material;
measuring a first capacitance (C_{int meas1}) of the integral sensor element while the integral sensor element is exposed to a known first vapor concentration of the first analyte;
obtaining a first relative reference capacitance (C_{n1 ref1}) of a reference sensor element at the first vapor concentration of the first analyte;
calculating C_{int base} as C_{int meas1}/(1+C_{n1 ref1}); and
storing C_{int base} on the electronic device to provide the calibrated electronic sensor.

38. A method of using a calibrated electronic sensor, the method comprising:
providing a calibrated electronic sensor made according to the method of making a calibrated electronic sensor of claim 37;
measuring a capacitance (Cᵤₙₖ) of the integral capacitance sensor element while exposed to the unknown concentration of the specified analyte vapor at the standard temperature;
obtaining a relative capacitance (C_{unk rel})=(Cᵤₙₖ−C_{int base})/C_{int base};
comparing C_{unk rel} to a corresponding reference correlation in the reference library and obtaining the true concentration of the analyte vapor; and
at least one of:
recording the true concentration of analyte vapor to the computer readable medium; or
communicating the true concentration of the analyte vapor to the display member.
